(19) United States
(12) Patent Application Publication
(10) Pub. No.: US 2016/0204066 A1
(43) Pub. Date: Jul. 14, 2016

(54) SEMICONDUCTOR DEVICE AND FABRICATION METHOD THEREOF

(71) Applicant: Semiconductor Manufacturing International (Shanghai) Corporation, Shanghai (CN)

(72) Inventor: HUANXIN LIU, Shanghai (CN)

(21) Appl. No.: 14/992,390

(22) Filed: Jan. 11, 2016

(30) Foreign Application Priority Data
Jan. 9, 2015 (CN) 2015-10011878.X

(51) Int. Cl. H01L 23/538; H01L 21/3205; H01L 23/532; H01L 21/768

(52) U.S. Cl. CPC H01L 23/5383; H01L 21/76873; H01L 21/32051; H01L 23/53238

(57) ABSTRACT

The present disclosure provides a semiconductor device and fabrication method thereof. A dielectric layer is formed on a first surface of a semiconductor substrate. Trenches are formed in the dielectric layer and on the first surface of the semiconductor substrate. A metal seed layer is formed on sidewalls and bottom of each trench. The semiconductor substrate formed with the metal seed layer is placed inside an electroplating tank containing an electroplating solution. The electroplating tank is controlled in a vacuum state. The semiconductor substrate formed with the metal seed layer is submerged into the electroplating solution. An electrochemical plating process is performed to deposit a metallic material on the metal seed layer to form a metal interconnect structure in the trenches.

### CROSS-REFERENCES TO RELATED APPLICATIONS

This application claims the priority of Chinese patent application No. CN201510011878.X, filed on Jan. 9, 2015, the entire content of which is incorporated herein by reference.

### FIELD OF THE DISCLOSURE

The present disclosure relates to the field of semiconductor technologies and, more particularly, relates to a semiconductor device and fabrication method thereof.

### BACKGROUND

With the rapid development of integrated circuits (ICs) manufacturing technology, the traditional IC manufacturing process nodes decrease and the sizes of integrated circuit devices continue to shrink. The number of semiconductor devices formed on a wafer continues to increase. The integrated circuit manufacturing technology innovations continue to improve the performance of IC devices.

In order to meet the requirements for accommodating the increasing number of semiconductor devices, a multilayer structure is usually used to form semiconductor devices on a wafer. The adjacent layers of semiconductor devices are electrically connected with each other through metal interconnect structures. Thus the number of semiconductor devices formed on a particular wafer area can be increased to improve the integration density of semiconductor devices.

FIG. 1 illustrates a schematic view of a conventional fabrication method of forming semiconductor devices with a multilayer structure. The method includes the following. A semiconductor substrate 10 is provided. Transistors (not shown), metal interconnect structures and other suitable semiconductor structures are formed on the semiconductor substrate 10. A first dielectric layer 11 is formed on the semiconductor substrate 11. Then a trench 12 is formed in the first dielectric layer 11. The trench 12 is filled up with an electrically conductive material such as copper. A first conductive plug 121 and metal interconnect wires are formed as a metal interconnect structure.

The first conductive plug 121 is electrically connected with the semiconductor device in the first dielectric layer 11. Another semiconductor device (not shown) is formed in the first dielectric layer 11 which is also electrically connected with the first conductive plug 121. A second dielectric layer 13 is formed on the first dielectric layer 11. The process of forming the first conductive plug 121 and metal interconnect wires in the first dielectric layer 11 is repeated to form a second conductive plug 14 and metal interconnect wires in the second dielectric layer 13. The process is repeated iteratively to form semiconductor devices with a multilayer structure on the same semiconductor substrate.

However, using the conventional semiconductor manufacturing technology, the metal interconnect structures formed in each dielectric layer may have poor performance and cannot satisfy the needs of semiconductor technology growth.

The disclosed devices and methods are directed to solve one or more problems set forth above and other problems in the art.

### BRIEF SUMMARY OF THE DISCLOSURE

One aspect of the present disclosure provides a method of forming a semiconductor device. A dielectric layer is formed on a first surface of a semiconductor substrate. Trenches are formed in the dielectric layer and on the first surface of the semiconductor substrate. A metal seed layer is formed on sidewalls and bottom of each trench. The semiconductor substrate formed with the metal seed layer is placed inside an electroplating tank containing an electroplating solution. The electroplating tank is controlled in a vacuum state. The semiconductor substrate formed with the metal seed layer is submerged into the electroplating solution. An electrochemical plating process is performed to deposit a metallic material on the metal seed layer to form a metal interconnect structure in the trenches.

Another aspect of the present disclosure provides a semiconductor device. The semiconductor device includes a semiconductor substrate and a dielectric layer on a first surface of the semiconductor substrate; and a metal interconnect structure through the dielectric layer and on the first surface of the semiconductor substrate. The metal interconnect structure is formed by: forming a trench through the dielectric layer and on the first surface of the semiconductor substrate, forming a metal seed layer on sidewalls and bottom of the trench; placing the semiconductor substrate formed with the metal seed layer inside an electroplating tank that contains an electroplating solution and is controlled in a vacuum state; submerging the semiconductor substrate formed with the metal seed layer into the electroplating solution; and performing an electrochemical plating process to deposit a metallic material on the metal seed layer to form the metal interconnect structure in the trench.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates a schematic diagram of the conventional conductive plug fabrication process;

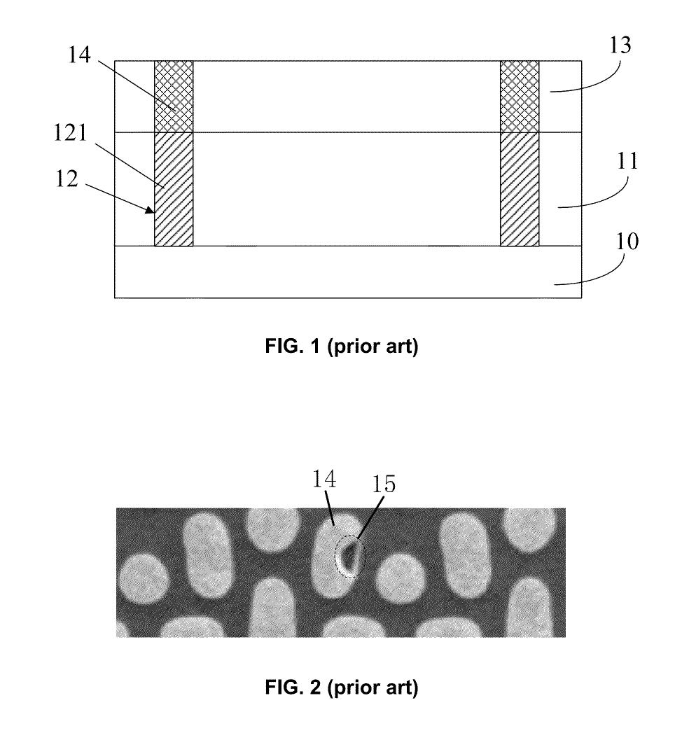

FIG. 2 is a scanning electron microscope (SEM) image of a conductive plug formed using the conventional fabrication process;

FIGS. 3-6 illustrate cross sectional structures of an exemplary semiconductor structure corresponding to certain stages of a fabrication process consistent with various disclosed embodiments; and

FIG. 7 illustrates a flow chart of an exemplary method for fabricating a multilayer semiconductor structure consistent with various disclosed embodiments.

### DETAILED DESCRIPTION

Reference will now be made in detail to exemplary embodiments of the invention, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all of the embodiments of the present invention. Based on the disclosed embodiments, persons of ordinary skill in the art may derive other embodiments consistent with the present disclosure, all of which are within the scope of the present invention.

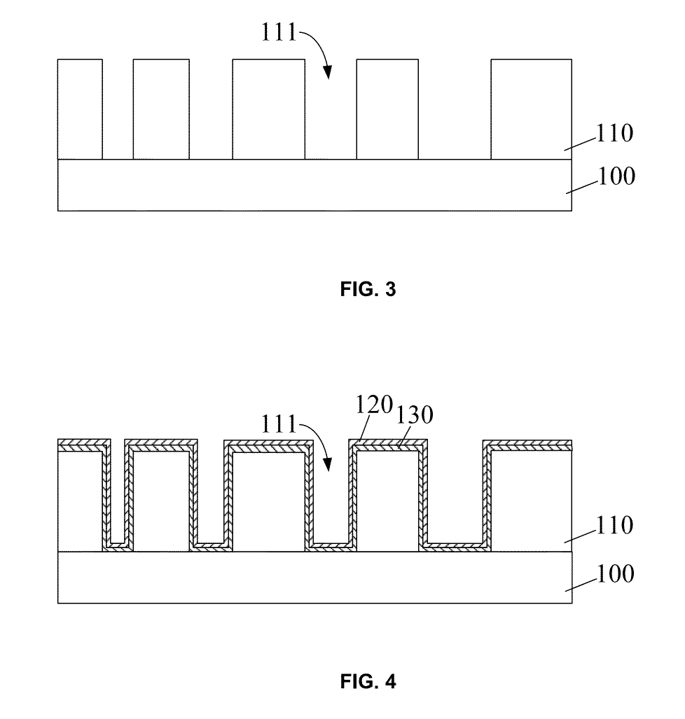

FIG. 2 is a SEM image of a conductive plug formed using a conventional fabrication process. In FIG. 2, a large number of voids 15 can be seen in a conventional conductive plug. In the life span of the semiconductor device, the subsequently formed conductive plugs may be disconnected, have high resistance and/or electron migration failures, or have other defects (same defects may affect the interconnect wires). Thus, the performance of the formed semiconductor device may be reduced.

In A conventional fabrication process, metallic material, such as copper, may be used to form the metal interconnect structure. Initially, a metal seed layer such as a copper seed layer may be formed on the bottom and sidewalls of the trench in the semiconductor substrate. Then, the semiconductor substrate may be submerged into an electroplating solution such as copper sulfate solution contained in an electroplating tank. Using the metal seed layer as the cathode, copper (Cu²⁺+2e-→Cu) may be deposited on the metal seed layer to fill up the trench and to form the metal interconnect structure.

After the semiconductor substrate is submerged into the electroplating solution, some air in the trench of the semiconductor substrate may not be released quickly enough. In the subsequent electroplating process, the air bubbles may be trapped in the deposited metal and may form voids in the metal interconnect structure.

Further, in the electroplating process, a hydrogen gas may be produced on the cathode (2H⁺+2e-→H₂). The hydrogen gas may not be released quickly enough from the trench in the dielectric layer and may be trapped in the metal deposited in the trench to form voids in the metal interconnect structure. The voids may affect the performance of the metal interconnect structure.

More voids may be formed in the metal interconnect structure, when the IC process nodes continue to shrink and result in an increased depth to width ratio of the trench in the dielectric layer. In the process when the semiconductor substrate is submerged into the electroplating solution, the residual air and/or the hydrogen gas produced during the electroplating process may be more difficult to escape due to the high depth to width ratio of the trench. More voids may be formed in the metal interconnect structure and more performance degradation may occur to the metal interconnect structure.

The present disclosure provides a method of forming a multilayer semiconductor device including the following steps.

A semiconductor substrate is provided. A trench is formed on the surface of the semiconductor substrate. A metal seed layer is formed on the sidewalls and the bottom of the trench.

An electroplating tank is provided. The electroplating tank contains an electroplating solution. The semiconductor substrate formed with the metal seed layer is placed into the electroplating tank. The electroplating tank is put into a vacuum state. The semiconductor substrate formed with the metal seed layer is submerged into the electroplating solution. Using electrochemical plating process, a metal material is deposited onto the metal seed layer to fill up the trench and to form the metal interconnect structure.

Because the electroplating tank is in a vacuum state and the air pressure must be balanced throughout the electroplating tank, the air located in the trench of the semiconductor substrate may be quickly escaped from the trench. When the semiconductor substrate is submerged into the electroplating solution, the residual air in the trench is already reduced or removed. In the subsequent electrochemical plating process, the total number and the individual size of the voids formed in the metal interconnect structure are reduced. The formed metal interconnect structure is optimized and the performance is improved.

The above objectives, features and advantages of the present disclosure can be more fully understood with reference to the following specific embodiments of the disclosure described in detail below.

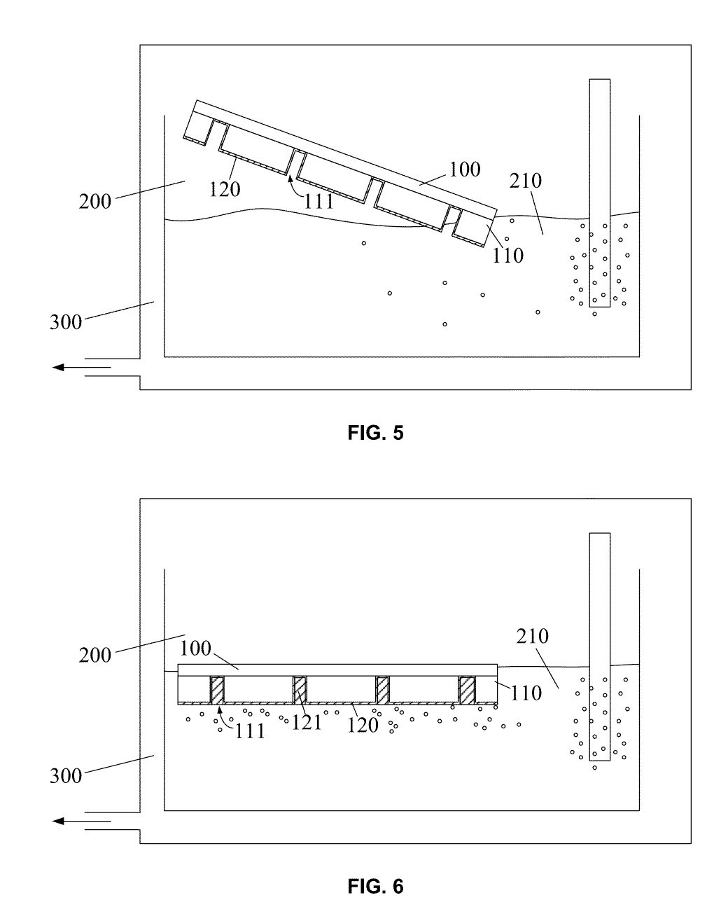

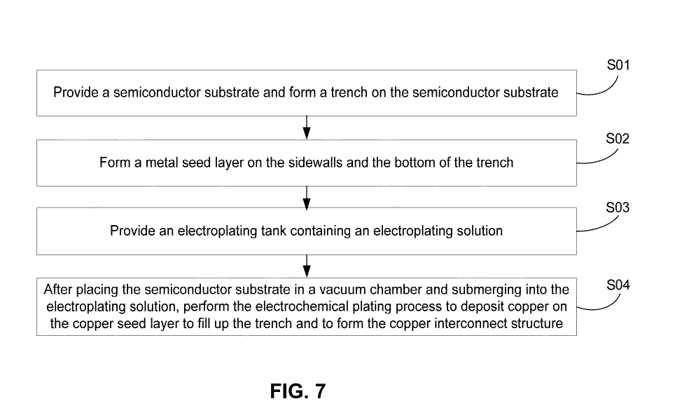

FIGS. 3-6 illustrate cross sectional structures of an exemplary semiconductor structure corresponding to certain stages of a fabrication process consistent with various disclosed embodiments. FIG. 7 illustrates a flow chart of an exemplary method for fabricating a multilayer semiconductor structure consistent with various disclosed embodiments.

It should be noted that for ease of showing the semiconductor device structure in each step of the exemplary embodiments, the graphical structure and the ratio of the dimensional sizes of the drawings may be slightly different, but the difference in the respective drawings should not affect the scope of protection of the present disclosure.

In one embodiment, the method of forming a semiconductor device is provided as follows.

As shown in FIG. 7, at the beginning of the fabrication process, a semiconductor substrate is provided to form a trench and the trench is later used to form a metal interconnect structure (S01). FIG. 3 illustrates a cross-sectional view of a corresponding structure of the exemplary semiconductor device consistent with the disclosed embodiments.

As shown in FIG. 3, a semiconductor substrate 100 may be provided. A trench 111 may be formed in the semiconductor substrate 100. The trench 111 may be later used to form a metal interconnect structure.

The semiconductor substrate 100 may include a substrate, a dielectric layer on the substrate, a semiconductor material layer and semiconductor device structures such as transistors, metal interconnect structures located in the substrate, the dielectric layer and the semiconductor material layer.

In one embodiment, the semiconductor substrate may include a semiconductor substrate 100, a dielectric layer 110 located on the semiconductor substrate 20, and a trench 111 formed in the dielectric layer 110.

The semiconductor substrate 100 may be made of silicon. In other embodiments, the semiconductor substrate 100 may be made of germanium, silicon germanium, gallium arsenide or other suitable semiconductor material. The semiconductor substrate 100 may also be made of a composite structure such as silicon on insulator.

Any commonly used semiconductor substrate may be used for the semiconductor substrate in the present disclosure. Those skilled in the art can select the type of the semiconductor substrate 100 based on the semiconductor devices formed on the semiconductor substrate. Therefore the type of the semiconductor substrate should not limit the scope of the present disclosure.

In one embodiment, the dielectric layer 110 is made of a dielectric material. The dielectric material may be a low K dielectric material (K is less than or equal to 3.0) or a ultra low K dielectric material (K is less than or equal to 2.6), such as porous silicon oxide and carbon doped silicon oxide, etc. to effectively reduce the parasitic capacitance between the metal interconnect structures subsequently formed in the dielectric layer 110.

In one embodiment, the dielectric layer 110 is made of silicon oxide. The formation process thereof may include physical vapor deposition (PVD) or atomic layer deposition (ALD), etc. The present disclosure does not limit the material of the dielectric layer or the formation process thereof.

To form the trench 111, a patterned mask layer (not shown) may be formed on the dielectric layer 110. The patterned mask layer may be used as an etch mask to etch the dielectric layer 110 to form the trench 111. The formation process for the patterned mask layer and the etching process for the dielectric layer using the patterned mask layer are matured in the art and are not repeated herein.

In one embodiment, the trench 111 may pass through the dielectric layer 110 to expose the semiconductor devices such as interconnect structures in the semiconductor substrate 100, and may be used later to form the metal interconnect structures.

In other embodiments, the trench 111 may not pass through the dielectric layer 110. The present disclosure does not limit the structure of the trench 111.

Returning to FIG. 7, a metal seed layer is formed on the sidewalls and the bottom of the trench (S02). FIG. 4 illustrates a cross-sectional view of a corresponding structure of the exemplary semiconductor device consistent with the disclosed embodiments.

As shown in FIG. 4, a metal seed layer 120 may be formed on the sidewalls and the bottom of the trench 111.

In one embodiment, the metal seed layer 120 may be a copper seed layer and the subsequently formed metal interconnect structure may be a copper interconnect structure.

In one embodiment, the formation process for the copper seed layer 120 may be physical vapor deposition (PVD).

Optionally, as shown in FIG. 4, after the trench 111 is formed in the dielectric layer 110, but before the metal layer 120 is formed, the disclosed method may further include a step of forming a diffusion barrier layer 130 on the sidewalls and the bottom of the trench 111. The metal seed layer may be formed on the diffusion barrier layer.

The diffusion barrier layer 130 may be made of Ta, TaN, etc. The diffusion barrier layer 130 may have a single layer structure or a multilayer structure. The formation process thereof may include PVD or CVD, etc.

In one embodiment, the diffusion barrier layer 130 is made of

TaN.

The diffusion barrier layer 130 may effectively prevent the atoms of the later formed metal interconnect structure from diffusing into the dielectric layer 110 and may effectively improve the bonding between the subsequently formed metal interconnect structure and the dielectric layer 110. Thus, the performance of the formed semiconductor devices may be improved.

Returning to FIG. 7, an electroplating tank containing an electroplating solution is provided (S03). FIG. 5 illustrates a cross-sectional view of a corresponding structure of the exemplary semiconductor device consistent with the disclosed embodiments.

As shown in FIG. 5, an electroplating tank 200 containing an electroplating solution 210 may be provided. The electroplating tank 200 may be used to perform the electrochemical plating process to deposit metal material onto the metal seed layer 120 on the semiconductor substrate 100 to form a metal interconnect structure filled up the trench 111 in the dielectric layer 110.

In one embodiment, the metal seed layer 120 may be a copper seed layer. The electroplating solution 210 may be a copper sulfate solution.

The semiconductor substrate 100 formed with the metal seed layer 120 may be placed inside the electroplating tank 200. Then the electroplating tank 200 may be put into a vacuum state. The interior of the electroplating tank may be in a negative pressure state. The air pressure inside the electroplating tank 200 may be less than the atmospheric pressure.

In one embodiment, the electroplating tank 200 may be placed inside a vacuum chamber 300. An air pump (not shown) may be used to continuously remove the air/gas from the vacuum chamber 300 (e.g., containing the electroplating tank) to maintain a vacuum state inside the vacuum chamber 300 (e.g. containing the electroplating tank 200).

In other embodiments, the semiconductor substrate 100 formed with the metal seed layer 120 may be directly placed inside the vacuum chamber 300. Meanwhile the air/gas in the electroplating tank 200 may be removed to keep the electroplating tank 200 in a negative air pressure state. Such modification does not limit the scope of protection of the present disclosure.

Referring to FIG. 5, the semiconductor substrate 100 formed with the metal seed layer 120 is submerged into the electroplating solution 210. Using the electrochemical plating process, metallic material is deposited on the metal seed layer 120 until the trench 111 is filled up.

In one embodiment, the electroplating tank 200 may be in a negative air pressure state. When the semiconductor substrate 100 is placed inside the vacuum chamber 300, following the pressure balance law, the air/gas in the trench in the dielectric layer may be quickly released. Residual air/gas in the trench may be minimized. In the subsequent electrochemical plating process, copper may be deposited on the copper seed layer 120 in the trench 111. Fewer air/gas may be trapped in the trench 111 and fewer voids may be formed in the copper interconnect structure.

Optionally, to submerge the semiconductor substrate 100 formed with the metal seed layer 120 into the electroplating solution 210, the surface of the semiconductor substrate 100 with the trench 111 may face toward the bottom of the electroplating solution 210 and then the semiconductor substrate may be submerged into the electroplating solution. The above process may make the metal seed layer in full contact with the electroplating solution 210 to improve the quality of the metal deposited by the electrochemical plating process.

Optionally, when the semiconductor substrate 100 is submerged into the electroplating solution 210, the semiconductor substrate may keep an angle between the surface of the dielectric layer 110 and the surface of the electroplating solution 210.

After the semiconductor substrate 100 is submerged into the electroplating solution 210, the trench 111 may be completely sealed by the electroplating solution. When the semiconductor substrate 100 tilted with an angle is gradually submerged into the electroplating solution 210, the electroplating solution 210 may be able to push out the air bubbles in the trench 111. Thus, fewer residual air/gas may be trapped in the trench 111 after the semiconductor substrate 100 is submerged into the electroplating solution 210.

In one embodiment, in the electrochemical plating process, the semiconductor substrate 100 formed with the trench 111 may be submerged into the electroplating solution while the surface opposite to the trench 111 remains out of the electroplating solution 210. This ensures that when metallic material is deposited on the metal seed layer, the bottom surface (that is out of the electroplating solution 210) of the semiconductor substrate 100 may avoid being electroplated such that the performance of the subsequently formed semiconductor devices may not be affected.

The electroplating tank may be in a vacuum state. When the semiconductor substrate 100 is submerged into the electroplating solution 210, the air/gas in the trench 111 may be released. Insufficient vacuum may affect the effectiveness of releasing the air/gas in the trench 111.

In one embodiment, the air/gas pressure inside the electroplating tank 200 may be less than or equal to about 100 torr in order to effectively release the air/gas in the trench 111.

Returning to FIG. 7, after the semiconductor substrate is placed in the vacuum chamber and submerged into the electroplating solution, the electrochemical plating process is performed to deposit copper on the copper seed layer to fill up the trench and to form the copper interconnect structure (SO4). FIG. 6 illustrates a cross-sectional view of a corresponding structure of the exemplary semiconductor device consistent with the disclosed embodiments.

As shown in FIG. 6, after the semiconductor substrate 100 is submerged into the electroplating solution 210, the electrochemical plating process may be performed to deposit copper 121 (Cu²⁺+2e-→Cu) on the copper seed layer 120 (as the cathode) to fill up the trench 111 and to form the copper interconnect structure.

However, in the electroplating process, another chemical reaction occurs at the cathode: 2H⁺+2e-→H₂. The newly produced hydrogen gas may form bubbles on the surface of the copper seed layer 120. The hydrogen gas may be trapped in the trench 111 and may form voids in the subsequently formed metal interconnect structure.

In one embodiment, in the electrochemical plating process, an air pump (not shown) or the equivalent may be used to continuously remove the air/gas in the electroplating tank 200.

In one embodiment, the air in the vacuum chamber 300 may be continuously removed to reduce the air pressure inside the electroplating tank 200 to release the air bubbles in the electroplating solution 210 and to minimize the residual air/gas in the trench 111 such that fewer air/gas may be trapped in the trench 111 in the process of depositing copper 121. Thus, the total number and the individual size of the voids subsequently formed in the copper interconnect structure may be reduced and the performance of the copper interconnect structure may be improved.

After the electrochemical plating process is used to deposit copper to fill up the trench in the dielectric layer, the semiconductor substrate 100 may be removed from the electroplating tank 200. The chemical mechanical polishing process may be used to planarize the semiconductor substrate to have the copper surface in the trench 111 coplanar with the surface of the dielectric layer 110. Then the copper interconnect structure is formed.

The present disclosure provides a method of forming semiconductor devices. After the metal seed layer is formed on the sidewalls and the bottom of the trench in the semiconductor substrate, the semiconductor substrate is placed inside the electroplating tank. The electroplating tank is put into a vacuum state. The semiconductor substrate is submerged into the electroplating solution. The electrochemical plating process is then performed.

After the electroplating tank is put into a vacuum state, due to the air pressure balance need, the air in the trench of the semiconductor substrate is quickly released. After the semiconductor substrate is submerged into the electroplating solution, the residual air in the trench is minimized. The total number and individual size of the voids subsequently formed in the metal interconnect structure are reduced. The metal interconnect structure is optimized to improve the performance.

Although the present invention is disclosed above with various embodiments, the present invention is not limited thereto. Anyone skilled in the art may make various changes and modifications without departing from the spirit and scope of the present invention. Therefore the scope of the present invention should be defined by the claims thereof.

What is claimed is:

1. A method of forming a semiconductor device, comprising:
forming a dielectric layer on a first surface of a semiconductor substrate;
forming trenches in the dielectric layer and on the first surface of the semiconductor substrate;
forming a metal seed layer on sidewalls and bottom of each trench;
placing the semiconductor substrate formed with the metal seed layer inside an electroplating tank containing an electroplating solution;
controlling the electroplating tank in a vacuum state;
submerging the semiconductor substrate formed with the metal seed layer into the electroplating solution; and
performing an electrochemical plating process to deposit a metallic material on the metal seed layer to form a metal interconnect structure in the trench.

2. The method of claim 1, further comprising:
continuously vacuumizing the electroplating tank to remove gas therein during the electrochemical plating process.

3. The method of claim 1, wherein:
the metal seed layer is a copper seed layer and the metallic material is copper.

4. The method of claim 1, wherein the step of submerging the semiconductor substrate with the metal seed layer into the electroplating solution includes:
inserting the semiconductor substrate into the electroplating solution such that the first surface of the semiconductor substrate forms an angle with a top surface of the electroplating solution.

5. The method of claim 1, wherein the step of submerging the semiconductor substrate formed with the metal seed layer into the electroplating solution includes:
inserting the semiconductor substrate into the electroplating solution such that the trenches on the first surface of the semiconductor substrate toward the electroplating solution.

6. The method of claim 1, wherein:
during the electroplating process, the trenches on the first surface of the semiconductor substrate are submerged into the electroplating solution, while the semiconductor substrate has a second surface opposite to the first surface, and the second surface maintains out of the electroplating solution.

7. The method of claim 1, wherein:
the electroplating tank has an inside air pressure less than or equal to about 100 torr.

8. The method of claim 1, further including:
before forming the metal seed layer, forming a diffusion barrier layer on the sidewalls and the bottom of the trench.

9. The method of claim 8, wherein:
the diffusion barrier layer is made of tantalum nitride.

10. The method of claim 3, wherein:
the electroplating solution is a copper sulfate solution.

11. The method of claim 3, wherein:
a physical vapor deposition process is used to form the copper seed layer.

12. A semiconductor device, comprising:
a semiconductor substrate;
a dielectric layer on a first surface of the semiconductor substrate; and
a metal interconnect structure through the dielectric layer and on the first surface of the semiconductor substrate, wherein the metal interconnect structure is formed by:
forming a trench through the dielectric layer and on the first surface of the semiconductor substrate, forming a metal seed layer on sidewalls and bottom of the trench; placing the semiconductor substrate formed with the metal seed layer inside an electroplating tank that contains an electroplating solution and is controlled in a vacuum state; submerging the semiconductor substrate formed with the metal seed layer into the electroplating solution; and performing an electrochemical plating process to deposit a metallic material on the metal seed layer to form the metal interconnect structure in the trench.

13. The device of claim 12, wherein:
the electroplating tank is continuously vacuumized during the electrochemical plating process.

14. The device of claim 12, wherein:
the metal seed layer is a copper seed layer and the metallic material is copper.

15. The device of claim 12, wherein:
the semiconductor substrate is inserted into the electroplating solution to allow the first surface of the semiconductor substrate to form an angle with a top surface of the electroplating solution.

16. The device of claim 12, wherein:
the semiconductor substrate is inserted into the electroplating solution to allow the trench on the first surface of the semiconductor substrate to face toward the electroplating solution.

17. The device of claim 12, wherein:
during the electroplating process, the trench on the first surface of the semiconductor substrate is submerged into the electroplating solution, while the semiconductor substrate has a second surface opposite to the first surface, and the second surface maintains out of the electroplating solution.

18. The device of claim 12, wherein:
the electroplating tank has an inside air pressure less than or equal to about 100 torr.

19. The device of claim 12, further including:
a diffusion barrier layer formed between the metal seed layer and the semiconductor substrate.

20. The device of claim 19, wherein:
the diffusion barrier layer is made of tantalum nitride.
